(19) United States
(12) Patent Application Publication
(10) Pub. No.: US 2013/0325376 A1
(43) Pub. Date: Dec. 5, 2013

(54) SYSTEMS AND METHODS FOR DETERMINING A POWER PHASE AND/OR A PHASE ROTATION

(71) Applicants: Thomas Edwin Turicchi, JR., Dallas, TX (US); Row Zeighami, McKinney, TX (US); Charles W. Cochran, Spring, TX (US)

(72) Inventors: Thomas Edwin Turicchi, JR., Dallas, TX (US); Row Zeighami, McKinney, TX (US); Charles W. Cochran, Spring, TX (US)

(21) Appl. No.: 13/984,608

(22) PCT Filed: Apr. 7, 2011
(86) PCT No.: PCT/US2011/031580

§ 371 Date: Aug. 9, 2013

(51) Int. Cl. G01R 25/00

(52) U.S. Cl. CPC G01R 25/00
USPC 702/60

(57) ABSTRACT

One example discloses a system for determining a power phase and/or a phase rotation in a three-phase power system. The system can comprise at least three different computer nodes that communicate over a network, wherein each of the at least three different computer nodes receives a power signal comprising (i) one of three separate single phase power signals of a three-phase power signal or (ii) a three-phase power signal. The at least three different computer nodes can comprise a master computer node to determine (i) the phase of the power signal provided to each of the at least three computer nodes and/or (ii) a phase rotation of the power signal provided to each of the at least three computer nodes. The determination can be based on power data that characterizes waveform properties of the power signal provided to each of the at least three computer nodes.

### BACKGROUND

Three-phase electric power is a common method of alternating-current electric power distribution. Three-phase electric power is a polyphase system and is the most common method used by grids worldwide to transfer power. A three-phase system is generally more economical than others because it uses less conductor material to transmit electric power than equivalent single-phase or two-phase systems at the same voltage.

Single-phase loads may be connected to a three-phase electrical power system in two ways. A load may be connected across two of the three-phase conductors or a load can be connected from a live phase conductor to the system neutral. Where the line-to-neutral voltage is a standard utilization voltage, individual single-phase utility customers or loads may each be connected to a different phase of the supply. Where the line-to-neutral voltage is not a common utilization voltage single-phase loads can be supplied by individual step-down transformers.

### BRIEF DESCRIPTION OF THE DRAWINGS

FIG. 1 illustrates an example of a system for determining a power phase and/or phase rotation in a three-phase power system.

FIG. 2 illustrates an example of a three-phase power signal.

FIG. 3 illustrates an example of a computer system for determining a power phase and/or phase rotation in a three-phase power system.

FIG. 4 illustrates an example of a single phase power signal provided from a three-phase power signal.

FIG. 5 illustrates another example of the single phase power signal provided from a three-phase power signal.

FIG. 6 illustrates another example of a system for determining a power phase and/or phase rotation in a three-phase power system.

FIG. 7 illustrates a flowchart of an example method for determining a power phase and/or phase rotation in a three-phase power system.

FIG. 8 illustrates another flowchart of another example method for determining a power phase and/or phase rotation in a three-phase power system.

FIG. 9 illustrates an example of a computer system that can be employed to implement the systems and methods illustrated in FIGS. 1-8.

### DETAILED DESCRIPTION

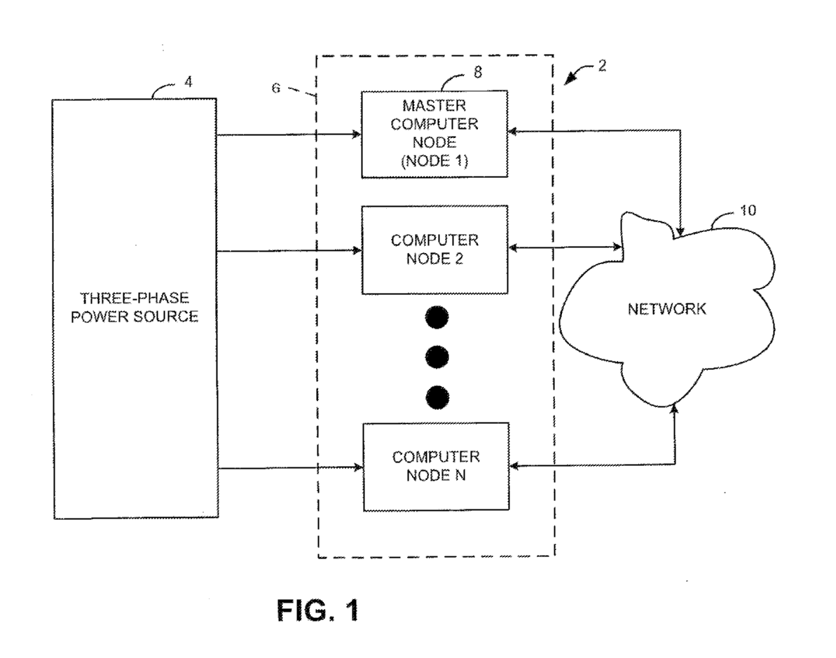

FIG. 1 illustrates an example of a system 2 for determining a power phase and/or a phase rotation in a three-phase power system. The system 2 can include a three-phase power source 4. The three-phase power source 4 can also be referred to as a power distribution unit (PDU). In other examples, the three-phase power source 4 could be implemented, for example, as an uninterruptable power supply (UPS), a transformer, etc. The three-phase power source 4 can be implemented, for example as a power source that can provide alternating current (AC) at three different phases, wherein each phase of the three-phase power source 4 is 120 out of phase with the other two phases of the three-phase power source 4. The three-phase power source 4 can provide electrical power to N number of computer nodes 6, where N is an integer greater than or equal to three. The computer nodes 6 could be implemented, for example, as computers (e.g., servers) in a server rack system, such as a blade server system. In some examples, a given computer node 6 of the N number of computer nodes 6 could be implemented in and/or as the three-phase power source 4 (e.g., in a smart PDU). In such a situation, it is considered that the given computer node 6 could provide a power signal to the remaining computer nodes 6 of the N number of computer nodes 6,

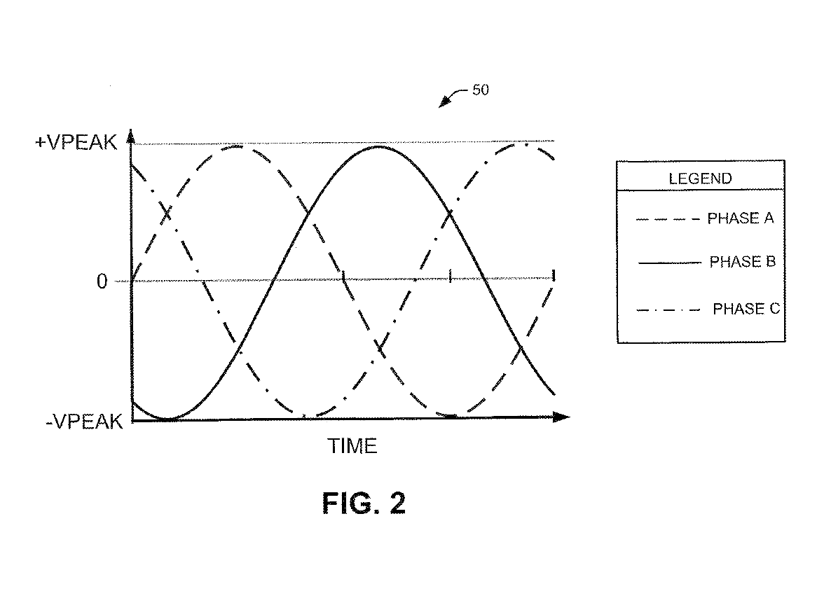

FIG. 2 illustrates an example of a three-phase power signal 50 that could be provided, for example, by the three-phase power source 4 illustrated in FIG. 1. In FIG. 2, the voltage of each phase, namely phase A, phase B and phase C (respectively labeled in FIG. 2 as “PHASE A”, “PHASE B” and “PHASE C”) is plotted as a function of time. Each of phase A, phase B and phase C can each be implemented as a sinusoidal wave that swings between a positive peak voltage, +Vₚₑₐₖ (labeled in FIG. 1 as “+VPEAK”) and a negative peak voltage, −Vₚₑₐₖ (labeled in FIG. 1 as “−VPEAK”). Moreover, each of phase A, phase B and phase C can have the same frequency (e.g., 60 Hz or 50 Hz). Furthermore, as illustrated in FIG. 2, each of phase A, phase B and phase C are 120 out of phase with the other 2 phases. That is, phase A is 120 out of phase with both phase B and phase C. Moreover, to drive a single phase load with a single phase signal, such as one of the N computer nodes 6 illustrated in FIG. 1, two different configurations can be employed. In a first example, one of phase A phase B and phase C can be provided to a given load, and that given load can be connected to a neutral (e.g., ground) terminal. In another example, a single phase signal can be generated from providing one of phase A, phase B and phase C to an input terminal of the given load, and coupling an output terminal of the given load to a different phase. For instance, phase A could be coupled to the input terminal of the given load, and phase B could be coupled to the output terminal of the given load. In either situation, the signal provided to the given load can be referred to as a single phase signal. In other examples, such as a situation where the N number of computer nodes 6 illustrated in FIG. 1 are implemented as three-phase devices, each of phase A, phase B and phase C can be provided to each of the N number of computer nodes 6.

Referring back to FIG. 1, a first computer node 6 of the N number of computer nodes 6 can be referred to as a master computer node 8 (e.g., a central management station). In some examples, each computer node 6 of the N number of computer nodes 6 receives one or two phase or phases of power from the three-phase power source 4. For instance, the system 2 can be configured as a wye (Y) connected system, wherein each of the computer nodes 6 can be configured to receive two phases of power from the three-phase power source 4. In another example, the system 2 can be configured as a delta (A) connected system. In such a situation, each of the N computer nodes 6 can be configured to receive one phase from the three-phase power source 4. In other examples, the N number of computer nodes 6 can be implemented as three-phase devices, such that each of the N number of computer nodes 6 receives all three phases from the three-phase power source 4.

Ideally, in some examples. each phase of the three-phase power source 4 shares a one third portion of a total load of the three-phase power source, which can be referred to as a balanced load. However, a balanced load can be difficult to achieve. First, such a balanced load typically requires knowledge of a phase output at a given power port of the three-phase power source 4. Moreover, is also common that a configuration that is initially set up as a balanced load has changes, for example, due to hardware changes to become an unbalanced load, wherein one or two of the phases of the three-phase power source drives more than one third of the total load of the three-phase power source 4. An unbalanced load in a three-phase system has undesirable effects, such as loss of efficiency, and possible damage to equipment employed to transmit the three-phase power (e.g., a transformer). The system 2 provides a mechanism for determining the phase or phases that power a given computer node 6 of the N computer nodes 6.

In other examples, such as a situation where the N number of computer nodes 6 are implemented as three-phase devices, the N number of computer nodes 6 can be arranged to provide a correct phase rotation. For instance, in the example illustrated in FIG. 2, each of the N number of computer nodes 6 could be configured to receive one of four different phase rotations, namely phase rotation (i) A-B-C, phase rotation (ii) A-C-B, phase rotation (iii) B-A-C or phase rotation (iv) C-B-A. In a three-phase power system where the three-phase power source 4 is arranged with a correct phase rotation, each of the N number of computer nodes 6 would be configured with the same phase rotation. In a three-phase power system where the three-phase power source 4 is configured with an incorrect (e.g., out of order) phase rotation, two different computer nodes 6 of the N number of computer nodes 6 could be configured with different phase rotations. For instance, in a three-phase power system wherein the three-phase power source 4 is configured with an incorrect (e.g., out of order) phase rotation, the first computer node 8 of the N number of computer nodes 6 could be configured with phase rotation (i) and computer node 2 of the N number of computer nodes 6 could be configured with phase rotation (ii). Incorrect phase rotation can also result in sub-optimum power distribution.

The N computer nodes 6 can communicate over a network 10. The network 10 can be configured, for example, as a private network, or is a public network (such as the Internet). As one example, each of the computer nodes 6 can employ transmission control protocol/Internet protocol (TCP/IP) to communicate. Each of the computer nodes 6 can be configured to implement a synchronization mechanism, such as Network Time Protocol (NTP). NTP can be employed as a protocol for synchronizing the clocks of computer systems over packet-switched, variable-latency data networks. Moreover, although the present examples describe a synchronization process employing NTP, it is to be understood that other protocols (including possible proprietary protocols) could be employed as well. The master computer node 8 can send a synchronizing message to the other computer nodes 6 of the N computer nodes 6. The synchronizing message can cause internal clocks of each of the N computer nodes 6 to be synchronized, or at least substantially synchronized. The master computer node 8 can send a lime reference message to the other computer nodes 6 of the N computer nodes 6 over the network 10. The time reference message can include a time reference that defines a particular moment in time.

In response to receipt of the time reference message, the other computer nodes 6 can store power data in memory that characterizes waveform properties for a predetermined amount of time before and/or after the time reference for each power signal received at of the other computer nodes 6. Moreover, the master computer node B can also store power data in memory that characterizes waveform properties in a similar fashion in response to transmission of the time reference message. The predetermined amount of time could be, for example, about 2 seconds.

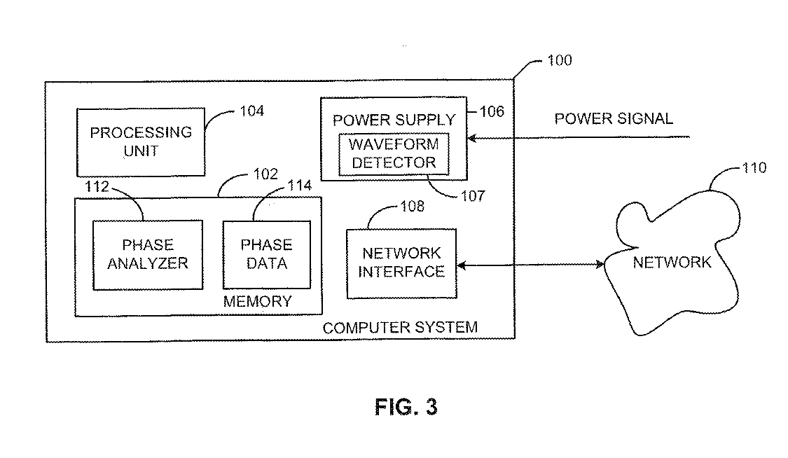

FIG. 3 illustrates an example of a computer system 100 that could be employed as a computer node 6 illustrated in FIG. 1. In the present example, the computer system 100 is described as implementing the master computer node 8 illustrated in FIG. 1, but it is to be understood that a similar computer system 100 could be employed for the other computer nodes 6 as well.

The computer system 100 can include, for example, memory 102 for storing computer executable instructions. Additionally, the computer system 100 can include a processing unit 104 for accessing the memory 102 and executing computer executable instructions. The processing unit 104 can be implemented, for example, as a processor core. The computer system 100 can receive a power signal at a power supply 106. The power signal can be implemented as one or two phases of AC power from a three-phase power source, or as a three-phase power signal from the three-phase power source, such as the three-phase power source 4 illustrated in FIG. 1. The power supply 106 can include a waveform detector 107. The waveform detector 107 can be implemented, for example, as software, hardware (e.g., an application-specific integrated circuit), or a combination of both (e.g., firmware), such as a power programmable integrated circuit (PIC). The waveform detector 107 can be implemented, for example, as a high resolution power measurer. The waveform detector 107 can be employed to detect power data that characterizes waveform properties of the power signal. The power data can be stored, for example, in the memory 102. In one example, the power data can be implemented as data representing a voltage of the power signal sampled at a predetermined sampling rate (e.g., 1000 Hz). In some examples, the power data could be implemented as a data structure with a voltage measured at points throughout a predetermined time period (e.g., 1-2 seconds), and a time stamp on each measured voltage. It is to be understood that in other examples, the time stamp may be omitted.

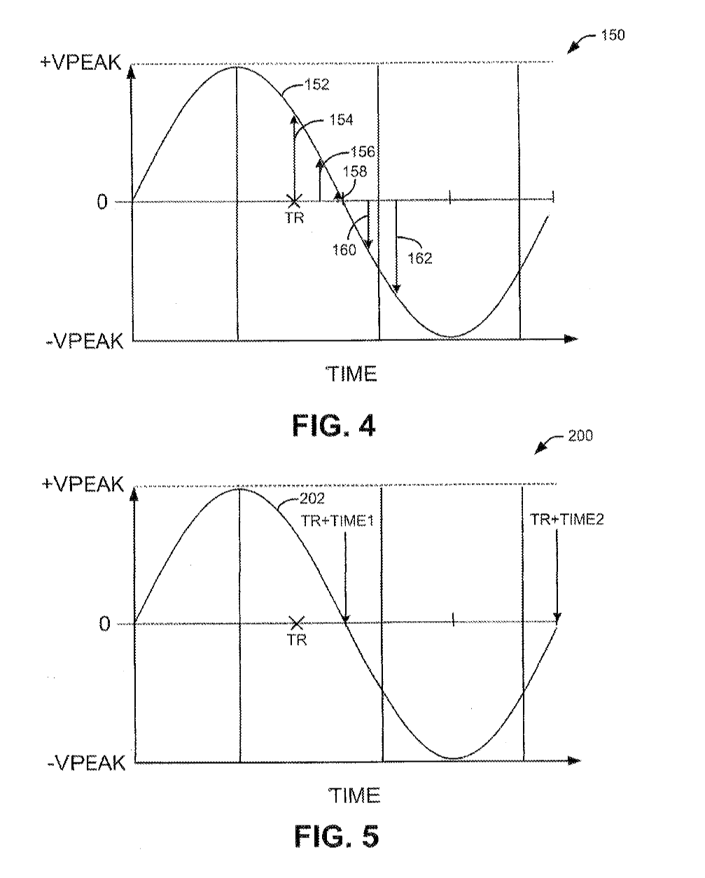

FIG. 4 illustrates an example of waveform sampling 150 that could be performed by the waveform detector 107 of FIG. 3. FIG. 3 includes an example of a power signal 152 that could be received at the power supply 106 of FIG. 3. The power signal 152 is illustrated as a voltage plotted as a function of time. The power signal 152 swings between a positive peak voltage, +Vₚₑₐₖ (labeled in FIG. 4 “+VPEAK”) and a negative peak voltage, −Vₚₑₐₖ (labeled in FIG. 4 “−VPEAK”). The power signal 152 can represent, for example, a voltage measured relative to a neutral terminal (e.g., ground), such as in a delta (Δ) configuration, or the power signal 152 could represent a difference between two phases of a three-phase power source, such as in a wye (Y) configuration. In either case, at a given time, such as the time reference mentioned with respect to FIG. 1 (labeled in FIG. 4 as ‘TR’) the power signal 152 can be sampled at regular time intervals, which time intervals can be referred to as a sampling rate. Samples taken of the power signal 152 are represented in FIG. 4 as arrows 154, 156, 158, 160 and 162. For purposes of simplification of explanation only five samples of the power signal 152 are illustrated in FIG. 4, but it is to be understood that more (or less) samples could be taken, and at different sampling rates. Thus, the power data recorded by the waveform detector 107 illustrated in FIG. 3 can include a series of sampled (e.g., measured) voltages at specific instances in time.

Additionally or alternatively, referring back to FIG. 3, in another example, the power data can be implemented as instances of time that the power signal crosses a certain threshold in a voltage curve (e.g., zero crossing, peaks, etc). FIG. 5 illustrates an example of recording and/or estimating instances times 200 that a power signal crosses certain thresholds. For purposes of simplification of explanation, the same power signal 202 that is shown in FIG. 4 is shown in FIG. 5. In FIG. 5, at a time before and/or after a time reference (labeled in FIG. 5 as ‘TR’) time instances of zero crossings can be recorded and/or estimated. As one example, at a first time instance after the time reference (labeled in FIG. 5 as “TR+TIME1”) a zero crossing can be recorded and/or estimated, which first time instance can correspond to the time reference plus a certain amount of time (e.g., 4100 microseconds). In a similar fashion, at a second time after the time reference (labeled in FIG. 5 as “TR+TIME2”) a second zero crossing can be recorded and/or estimated. Moreover, in some examples, instead of measuring the zero crossing directly, time instances of peak voltage can be determined, and the zero crossings can be estimated to be at half the time between a time of two voltage peaks. Furthermore, in some examples, the time instances of zero crossings can include data that indentifies a particular zero crossing as an upward crossing (e.g., increasing voltage) or a downward crossing (e.g., decreasing voltage). It is to be understood that the examples of sampling and threshold crossing illustrated in FIGS. 4 and 5 could also be employed in a similar fashion to detect waveform properties of individual phases of a three-phase power signal provided to a single three-phase device.

Referring back to FIG. 3 the computer system 100 can include a network interface 108 (e.g., a network interface card) that can be employed to communicate with other computer systems, such as the N computer nodes 6 illustrated in FIG. 1. over a network 110. A predetermined time intervals, which can be set, for example, by a user of the computer system 100, the computer system 100 can provide a time reference message via the network 110 to the other computer nodes, such as computer nodes 2-N, 6 illustrated in FIG. 1. As noted, in response to the time reference message, the other computer nodes each return power data that characterizes waveform properties of a power signal input into a given computer node for a predetermined time period (e.g., 1-2 seconds) that includes a period of time before and/or after a time reference included in time reference message. In a similar fashion, upon transmitting the time reference message, the computer system 100 can employ the waveform detector 107 to generate power data that characterizes waveform properties of the power signal provided to the power supply 106 of the computer system 100.

Upon receiving power data from each of the other computer nodes, a phase analyzer 112 stored in the memory 102, can be employed to collate power data from all computer nodes (including the computer system 100) that receive power from the same three-phase power source to determine which phase or phases is coupled to each of the computer nodes. Moreover, in an example where the N computer nodes 6 are implemented as three-phase devices, the phase analyzer 112 can be employed to determine a phase rotation for each of the computer nodes. For instance, in a first example, if each of the computer nodes is configured to sample a power signal at a predetermined sampling rate, in a manner described herein with respect to FIG. 3, the phase analyzer 112 can plot all of the sampled voltages for each computer node. In such a situation, the phase analyzer 112 can employ a waveform matching algorithm to determine which phase or phases of the three-phase power most closely match each waveform plotted by the phase analyzer 112 for each computer node. The waveform matching algorithm can employ, for example a best-fit sinusoidal estimate of time (relative to the time reference) of the zero crossing, or some other threshold (e.g., peak to peak) relative to the time reference. Thus. the phase analyzer 112 can determine which phase or phases of the three-phase power source are provided to each computer node, and in some examples, the order of rotation of the phases. Moreover, the predetermined time period can include a sufficient number of cycles (e.g., 30-60) for each phase of the three-phase power source to account for measurement error, frequency drift, etc. The phase analyzer 112 can store phase data 114 in the memory 102 that identifies which phase or phases (and in some examples, the phase rotation) of the three-phase power source are provided to each computer node.

Additionally or alternatively, in a second example, if each of the computer nodes is configured to record and/or estimate voltage threshold crossings, in a manner described herein with respect to FIG. 4, the phase analyzer 112 can employ a power timing algorithm to plot zero crossings (or other threshold crossing) for each computer node. From the zero crossings, the phase or phases and/or the phase rotation of the power signal provided from the three-phase power source provided to each computer node can be determined since each phase has the same (or substantially the same) frequency. That is, a given phase of the three-phase power source has zero crossings at predictable times, such that the identity of the given phase can be deduced if a sufficient number of zero-crossings are recorded and/or estimated for the given phase of the three-phase power source. For instance, if a given time reference is set at a time instance designated as 0 ms in a 60 Hz cycle, each cycle could have a time period of 16.6 ms, such that expected zero crossings could be estimated for each phase of the three-phase power source. Moreover, the predetermined time period can include a sufficient number of cycles (e.g., 30-60) for each phase in the three-phase power source to account for measurement error, frequency drift, etc. Thus, the phase analyzer 112 can store the phase data 114 that identifies which phase or phases and/or the phase rotation of the power signal provided from the three-phase power source are provided to each computer node. In either the first or second examples, the phase data 114 can be employed, for example, by other programs and/or users to ensure the three-phase power source has a balanced load and/or correct phase rotation. For instance, the phase data 114 can be employed, for example, to generate a power wiring map.

Referring back to FIG. 1, by employing the system 2, the phase or phases (and in some examples, phase rotation) provided from the three-phase power source 4 to each of the N computer nodes 6 can be determined. Moreover, since the N computer nodes 6 employ NTP and communicate over the network 10, no noise is added to the power signals provided to the power the N computer nodes 6 to make the determination. Thus, the system 2 is highly accurate in its determination of which phase of the three-phase power source 4 is provided to which computer node 6. Moreover, in examples in which the N computer nodes 6 are implemented as three-phase devices, the system 2 is highly accurate in its determination as to the phase rotation of a three-phase power signal provided from the power source 4 to each of the computer nodes 6.

Furthermore, in examples in which the N computer nodes 6 are implemented as three-phase devices, by determining the phases provided to each of the N computer nodes 6, phase remapping can be detected. Phase remapping can occur, for example, in situations where a phase of rotation of A-B-C illustrated in FIG. 2 is changed to a phase rotation of (a) B-C-A or phase rotation (b) C-A-B. In such a situation, the phase rotation order remains the same, but a phase change (e.g., phase remapping) has still occurred. The system 2 illustrated in FIG. 1 can detect such a phase remapping, even if the phase rotation order remains correct.

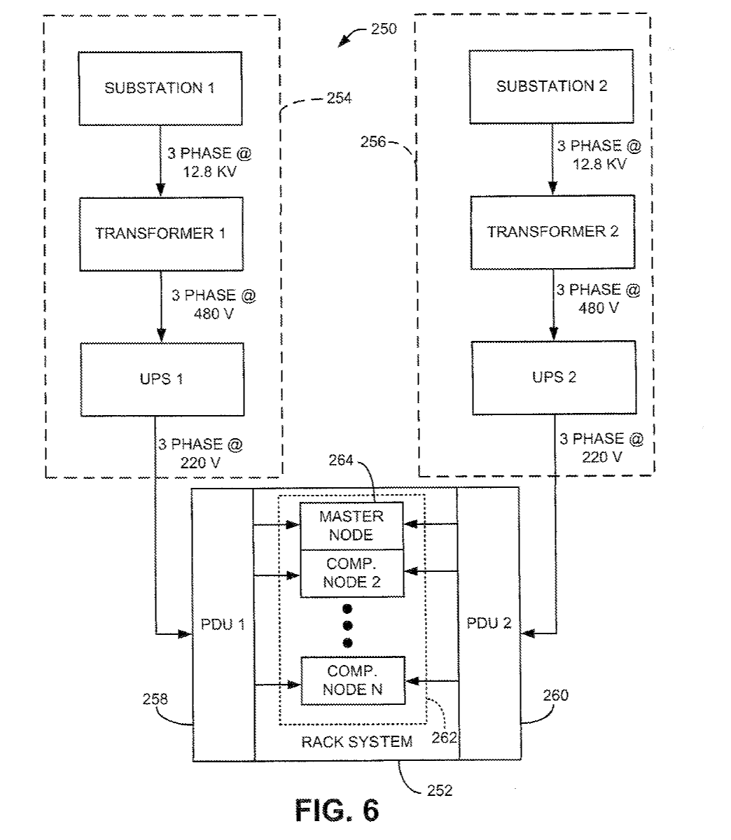

FIG. 6 illustrates another example of a system 250 for determining a phase and/or phase rotation of a three-phase power system. The system 250 includes a rack system 252 (e.g., a computer server rack) that receives redundant power. The rack system 252 receives a power signal from two separate power feeds, namely a first power feed 254 and a second power feed 256, as described herein. In the present example, two separate substations, namely substation 1 and substation 2 of each of the first and second power feeds 254 and 256 provide a high-voltage three-phase power signal, which can be implemented, for example, as a three-phase 12.8 kV AC power signal to respective transformers 1 and 2. Transformers 1 and 2 of each of the first and second power feeds 254 and 256 step down the high-voltage three-phase power signal, for example to a three-phase 480 V AC power signal and provides the stepped down power signal to respective uninterruptible power supplies (UPS) 1 and 2 of each of the first and second power feeds 254 and 256. UPS 1 and UPS 2 can filter out noise in the stepped down three-phase power signal received from the transformers 1 and 2 respectively. UPS 1 and UPS 2 can provide a three-phase 220 V AC power signal to respective power distribution units (PDU) 1 and 2, 258 and 260 of the rack system 252. PDU 1 and PDU 2, 258 and 260 can be implemented, in a manner similar to the three-phase power source illustrated in FIG. 1. In some examples, both the PDU 1 258 and the PDU 2 260 can provide single phase or three-phase power to N computer nodes 262 that can communicate on a network, wherein the first computer node of the N computer nodes 262 can be a master computer node 264. In other examples, a given computer node 262 of the N number of computer nodes 262 can be implemented in and/or as PDU 1 and/or the PDU 2 258 and 260. In the present example, it is to be understood that the term “single phase power” can indicate either a single phase to neutral signal (e.g., a delta (Δ) configuration) or two phases of the three-phase system (e.g., a wye (Y) configuration).

Configuring the system 250 in the manner illustrated in FIG. 6 allows for redundancy. That is, if any component of one of the first or second power feeds 254 or 256 fails, the rack system 252 will still continue to receive power from the other power feed. Moreover, the specific voltages shown and described with respect to FIG. 6 are only one example of many different configurations in which a redundant power system for the rack system 252 can be configured. In other configurations, additional transformers and circuit breakers could be implemented as well.

Each of the N computer nodes 262 can employ NTP (or a different time protocol) to synchronize internal clocks of the N computer nodes 262. Moreover, at specific times designated by a user of the master computer node 264, the master computer node 264 can provide the computer nodes 2-N 262 with a time reference message. In response, each of the N computer nodes 262 can activate high resolution power measurement to collect power data on the single phase or three-phase power signal provided from the PDU 1 258 and the single phase or three-phase power signal provided by the PDU 2 260. Based on power data collected at each of the N computer nodes 262 (including the master computer node 664), the master computer node 264 can employ either a waveform matching algorithm and/or a power timing algorithm in a manner described herein to determine which phase of both the PDU 1 and PDU 2, 258 and 260 is connected to which of the N computer nodes 262. Moreover, in examples where the N computer nodes 262 are configured as three-phase devices, the master computer node 264 can determine a phase rotation for a three-phase signal provided from both the PDU 1 and PDU 2 258 and 260 to each of the N computer nodes 262. Furthermore, since, in some examples the UPS 1 and the UPS 2 add a random amount of delay to power signals output by the UPS 1 of the UPS 2, the master computer node 264 can also distinguish between the power signal provided to a given computer node 262 from PDU 1 258 and the power signal provided to the given computer node 262 from PDU 2 260. In other examples, the UPS 1 and the UPS 2 can be programmed to add a specific amount of delay to output signals to assist in distinguishing between a power signal received from PDU 1 258 and a power signal received from PDU 2 260. Moreover, upon making such a determination, the master computer node 264 can store phase data that could be employed, for example, to generate a power wire mapping of the rack system 252.

By employing the system 250 illustrated in FIG. 6, a user of the rack system 262 can reconfigure the rack system 252 to ensure load balancing and/or correct phase rotation among each phase of each power feed. Such load balancing and/or correct phase rotation will ensure optimum power usage, and can help to avoid and/or illuminate inefficiencies and/or dangers in a power distribution system. Moreover, by employing the system 250, phase remapping from the UPS 1 and/or the UPS 2 can be detected. Remapping can occur, for example, in situations where a phase error occurs between the substation 1 and the transformer 1 and/or the substation 2 and the transformer 2. in such a situation, detection of phase remapping can avoid worsening imbalances due to a phase from UPS 1 and/or UPS 2 being wrongly identified.

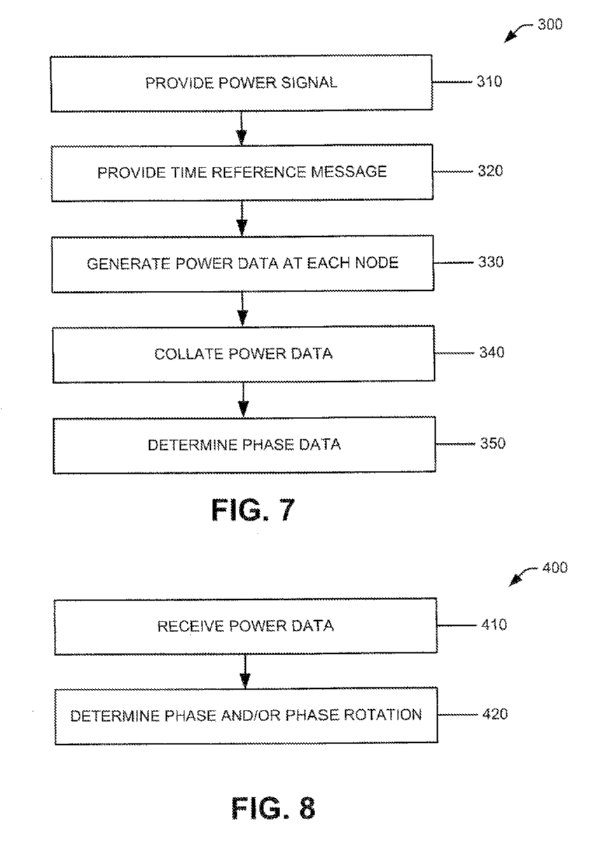

In view of the foregoing structural and functional features described above, example methodologies will be better appreciated with reference to FIGS. 7-8. While, for purposes of simplicity of explanation, the example methods of FIGS. 7-8 are shown and described as executing serially, it is to be understood and appreciated that the present examples are not limited by the illustrated order, as some actions could in other examples occur in different orders and/or concurrently from that shown and described herein.

FIG. 7 illustrates a flowchart of an example method 300 for determining a phase and/or phase rotation of a three-phase AC power signal. The method 300 could be implemented, for example, by the system 2 illustrated in FIG. 1 and/or the system 250 illustrated in FIG. 6. At 310, a three-phase power source can provide a single phase or three phase power signal to N computer nodes that communicate over a network. At 320, a time reference message can be provided from a master computer node (e.g., a first of the N computer nodes) to the 2-N computer nodes to which the single phase or three phase power signal is provided. The time reference message can include, for example, a time reference for each of the N computer nodes to begin a high resolution power measurement. The time reference message can be sent, for example over the network via a standard network protocol (TCP/IP).

At 330, in response to the time reference message, each of the N computer nodes can generate power data that characterizes waveform properties of the power signal provided to a given computer node for a predetermined amount of time before and/or after the time reference (e.g., 1-2 seconds). The power data can be generated, for example, by employing high-resolution power measurement at each of the N computer nodes. As one example, the power data can be generated by sampling one of the single phase or three phase power signals provided to a given computer node for a predetermined amount of time before and/or after the time reference. Additionally or alternatively, the power data can be generated by recording and/or estimating time instances that the single phase or three phase power signal provided to the given computer node crosses a predetermined threshold for a predetermined amount of time before and/or after the time reference. At 340, the master computer node can collate the power data to identify waveform properties of each power signal provided to each of the N computer nodes. At 350, upon collating the power data, the master computer node can determine phase data that identifies which phase (or phases) of the three-phase power source are coupled to which computer node and/or a phase rotation of the power signal provided to each computer node. By employing the method 300, the user can employ the phase data to configure the system, such that the three-phase power source is driving a balanced (or near balanced) load and/or the computer nodes are configured with a correct phase rotation.

FIG. 8 illustrates a flowchart of another example method 400 for determining a phase and/or phase rotation of a three-phase power signal. At 410, power data is received via a network. The power data can characterize waveform properties of a plurality of power signals provided to a plurality of computer nodes from a three-phase power source. At 420, a phase and/or phase rotation of each of the power signals provided to the plurality of computer nodes based on the power data can be determined.

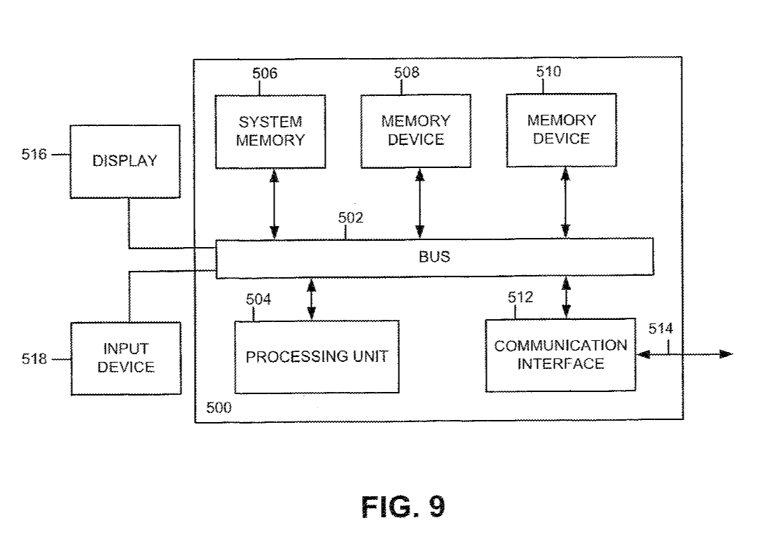

FIG. 9 is a schematic block diagram illustrating an example system 500 of hardware components capable of implementing examples disclosed in FIGS. 1-8, such as the computer nodes 6, 100 and 262 illustrated in FIGS. 1-6. The system 500 can include various systems and subsystems. The system 500 can be a personal computer, a laptop computer, a workstation, a computer system, an appliance, an application-specific integrated circuit (ASIC), a server, a server blade center, a server farm, etc.

The system 500 can include a system bus 502, a processing unit 504, a system memory 506, memory devices 508 and 510, a communication interface 512 (e.g., a network interface), a communication link 514, a display 516 (e.g., a video screen), and an input device 518 (e.g., a keyboard and/or a mouse). The system bus 502 can be in communication with the processing unit 504 and the system memory 506. The additional memory devices 508 and 510, such as a hard disk drive, server, stand alone database, or other non-volatile memory, can also be in communication with the system bus 502. The system bus 502 operably interconnects the processing unit 504, the memory devices 506-510, the communication interface 512, the display 516, and the input device 518. In some examples, the system bus 502 also operably interconnects an additional port (not shown), such as a universal serial bus (USB) port.

The processing unit 504 can be a computing device and can include an application-specific integrated circuit (ASIC). The processing unit 504 executes a set of instructions to implement the operations of examples disclosed herein. The processing unit can include a processing core.

The additional memory devices 506, 508 and 510 can store data, programs, instructions and any other information that can be needed to operate a computer. The memories 506, 508 and 510 can be implemented as computer-readable media (integrated or removable) such as a memory card, disk drive, compact disk (CD). or server accessible over a network. In certain examples, the memories 506. 508 and 510 can comprise text, images, video, and/or audio.

Additionally, the memory devices 508 and 510 can serve as databases or data storage that could, for example, store the phase data 114 illustrated in FIG. 3. Additionally or alternatively, the system 500 can access an external system through the communication interface 512, which can communicate with the system bus 502 and the communication link 514.

In operation, the system 500 can be used to implement, for example, a computer node, such as a server that can be employed in a system that can determine a power phase of a three-phase power signal. Computer executable logic for implementing the system, such as the memory 102 of the phase analyzer 112 illustrated in FIG. 3, can reside in the system memory 506, and/or in the memory devices 508 and/or 510 in accordance with certain examples. The processing unit 504 executes computer executable instructions originating from the system memory 506 and the memory devices 508 and 510. In such an example, the system memory 506 and/or the memory devices 508 and/or 510 could be employed, for example, to implement the memory 102 illustrated in FIG. 3. The term “computer readable medium” as used herein refers to a medium that participates in providing instructions to the processing unit 504 for execution.

Where the disclosure or claims recite “a,” “an,” “a first,” or “another” element, or the equivalent thereof, it should be interpreted to include one or more than one such element, neither requiring nor excluding two or more such elements. Furthermore, what have been described above are examples. It is, of course, not possible to describe every conceivable combination of components or methods, but one of ordinary skill in the art will recognize that many further combinations and permutations are possible. Accordingly, the invention is intended to embrace all such alterations. modifications. and variations that fall within the scope of this application. including the appended claims.

What is claimed is:

1. A system for determining a power phase and/or a phase rotation in a three-phase power system comprising:
at least three different computer nodes that communicate over a network, wherein each of the at least three different computer nodes receives a power signal comprising (i) one of three separate single phase power signals of a three-phase power signal or (ii) a three-phase power signal, the at least three different computer nodes comprising:
a master computer node to determine (i) the phase of the power signal provided to each of the at least three computer nodes and/or (ii) a phase rotation of the power signal provided to each of the at least three computer nodes, wherein the determination is based on power data that characterizes waveform properties of each power signal provided to each of the at least three computer nodes, wherein each of the at least three computer nodes generates a portion of the power data before and/or after a time reference identified in a message transmitted over the network.

2. The system of claim 1, wherein the three different computer nodes are to synchronize clocks by employing network time protocol (NTP).

3. The system of claim 1, wherein at least two of the three different computer nodes are to transmit a portion of the power data to the master computer node over the network.

4. The system of claim 3, wherein the power data characterizes the waveform properties of each power signal provided to each of the at least three computer nodes for a predetermined amount of time.

5. The system of claim 4, wherein a given computer node of the at least three computer nodes is to generate a portion of the power data by sampling one of the power signals provided to the given computer node over the predetermined amount of time.

6. The system of claim 5, wherein the given computer node of the at least three computer nodes is further to sample the one of the power signals provided to the given computer node at a predetermined sampling rate.

7. The system of claim 6. wherein the master computer node comprises a phase analyzer to determine which phase or phases of the three-phase power signal most closely match a waveform plotted by the phase analyzer for each computer node of the at least three computer nodes.

8. The system of claim 4, wherein a given computer node of the at least three computer nodes is to generate a portion of the power data by recording and/or estimating time instances that a power signal provided to the given computer node crosses a predetermined threshold over the predetermined amount of time.

9. A method for determining a power phase and/or a phase rotation in a three-phase power system comprising:
receiving power data via a network that characterizes waveform properties of a plurality of power signals provided to a plurality of computer nodes; and
determining (i) a phase and/or (ii) a phase rotation of each of the power signals provided to the plurality of computer nodes based on the power data.

10. The method of claim 9, further comprising providing a time reference message to at least two of the plurality of computer nodes.

11. The method of claim 10, further comprising generating a portion of the power data at each of the at least two computer nodes in response to receiving the time reference message.

12. The method of claim 11, wherein the generating comprises sampling a power signal provided to a given computer node of the plurality of computer nodes for a predetermined amount of time before and/or after a time reference identified in the time reference message.

13. The method of claim 11, wherein the generating comprises recording and/or estimating time instances that a power signal provided to a given computer node of the plurality of computer nodes crosses a predetermined threshold for a predetermined amount of time before and/or after a time reference identified in the time reference message.

14. A system for determining a phase and/or a phase rotation of a three-phase power system comprising;
first and second power feeds, the first and second power feeds each comprising:
a substation to provide a high voltage three-phase power signal;
a transformer to transform the high voltage three-phase power signal into a stepped down three-phase power signal; and
an uninterruptable power supply (UPS) to filter the stepped down power signal and provide a three-phase power signal; and a server rack comprising:
a first power distribution unit (PDU) that receives the three-phase power signal from the UPS of the first power feed and provides a first set of three single phase power signals;
a second PDU that receives the three-phase power signal from the UPS of the second power feed and provides a second set of three single phase power signals; and
at least three computer nodes that communicate over a network, wherein each of the at least three computer nodes receives a power signal from both the first PDU and the second PDU;
wherein a master computer node of the at least three computer nodes is to determine (i) which phase of the first PDU and the second PDU is connected to which computer node of the at least three computer nodes and/or (ii) a phase rotation of a power signal provided from the first PDU and the second PDU to each computer node of the at least three computer nodes, the determination being based on power data received at the master computer node over the network that characterizes waveform properties of each power signal provided to each of the at least three computer nodes, the master computer node is further to store data for generating at least a portion of a power wire mapping of the server rack.

15. The system of claim 14, wherein the master computer node makes the determination by employing at least one of a waveform matching algorithm and a power timing algorithm.
